(19) United States
(12) Patent Application Publication
(10) Pub. No.: US 2018/0322841 A1
(43) Pub. Date: Nov. 8, 2018

(54) SHIFT REGISTER CIRCUIT AND DISPLAY PANEL USING SAME

(71) Applicant: Chongqing HKC Optoelectronics Technology Co., Ltd., Chongqing (CN)

(72) Inventor: Yu-Jen CHEN, Chongqing (CN)

(21) Appl. No.: 15/556,093

(22) PCT Filed: May 17, 2017
(86) PCT No.: PCT/CN2017/084671

§ 371 Date: Sep. 6, 2017

(30) Foreign Application Priority Data
May 5, 2017 (CN) 201710313131.9

(51) Int. Cl. G09G 3/36; G11C 19/28; G02F 1/1335

(52) U.S. Cl. CPC G09G 3/3677; G09G 2310/0286; G02F 1/133528; G11C 19/287

(57) ABSTRACT

A shift register circuit includes shift registers and each including: a first through fourth switches: in the first switch: a control end electrically coupled to a first node, a first end electrically coupled to a frequency signal, and a second end electrically coupled to an output pulse signal; in the second switch: a control end electrically coupled to the first node, a first end of electrically coupled to the frequency signal, and a second end electrically coupled to a control signal; in the third switch: a control end electrically coupled to a control signal, a first end electrically coupled to a first direct-current signal, and a second end electrically coupled to the first node; in the fourth switch: a control end electrically coupled to the control signal, a first end electrically coupled to a second direct-current signal, and a second end electrically coupled to the first node.

### BACKGROUND

### Technical Field

This application relates to circuit structures in displays, and in particular, to a shift register circuit and a display panel using the same.

### Related Art

In recent years, with advancement of science and technologies, planar liquid crystal displays gradually proliferate because planar liquid crystal displays have advantages of being light and thin and the like. Currently, a drive circuit of a planar liquid crystal display is mainly implemented by connecting a panel to an external IC. However, the method cannot reduce product costs, and cannot enable panels to be thinner.

In addition, a liquid crystal display device generally has a gate drive circuit, a source drive circuit, and a pixel array. The pixel array has a plurality of pixel circuits. Each pixel circuit is opened or closed according to a scanning signal provided by the gate drive circuit, and displays a data image according to a data signal provided by the source drive circuit. Using the gate drive circuit as an example, the gate drive circuit generally has a plurality of shift registers, and outputs a scanning signal to the pixel array in a manner of transmitting, by a shift register, the scanning signal to a next shift register, to open the pixel circuits successively, so that the pixel circuits receive the data signal.

Therefore, in a process of manufacturing a drive circuit, a gate drive circuit is directly manufactured on an array substrate, so as to replace a drive chip manufactured by connecting a panel to an external IC. This technology referred to as gate driver on array (GOA) may be directly applied to a peripheral of the panel, thereby simplifying a manufacturing process, reducing product costs, and enabling a panel to be thinner. In the GOA technology, a speed at which a shift register pulls down a gate signal usually affects performance of driving a pixel array by the gate signal. However, the speed at which a shift register pulls down a gate signal is lowered because of time sequence setting of the existing panels and a leakage current possibly generated when a switch component in a shift register switches on or switches off for a voltage. If the speed of pull downing a gate signal can be effectively increased, a displayed image of the entire panel can be optimized, thereby improving quality of the displayed image. Therefore, to overcome the foregoing defect of the technology of a gate driver on array circuit substrate, a shift register circuit having low costs and being easy to process is provided.

### SUMMARY

To resolve the foregoing technical problem, an objective of this application is providing a shift register circuit, so that in a direct-current precharge mode, an active switch is added and is separately connected to a first direct-current signal and a second direct-current signal, so as to take turns to precharge an increase point, and reduce a pressure time when there is only one switch, thereby extending component service life, and improving product reliability and extending product service life.

The objective of this application is achieved and the technical problem of this application is resolved by using the following technical solutions. A shift register circuit according to this application comprises a plurality of shift registers, where each shift register comprises: a first switch, where a control end of the first switch is electrically coupled to a first node, a first end of the first switch is electrically coupled to a frequency signal, and a second end of the first switch is electrically coupled to an output pulse signal; a second switch, where a control end of the second switch is electrically coupled to the first node, a first end of the second switch is electrically coupled to the frequency signal, and a second end of the second switch is electrically coupled to a control signal; a third switch, where a control end of the third switch is electrically coupled to a control signal, a first end of the third switch is electrically coupled to a first direct-current signal, and a second end of the third switch is electrically coupled to the first node; and a fourth switch, where a control end of the fourth switch is electrically coupled to the control signal, a first end of the fourth switch is electrically coupled to a second direct-current signal, and a second end of the fourth switch is electrically coupled to the first node.

Another objective of this application is providing a liquid crystal display panel, comprising: a first substrate; a second substrate, disposed opposite the first substrate; a liquid crystal layer, disposed between the first substrate and the second substrate; the shift register circuit, disposed on the first substrate or the second substrate; a first polarizer, disposed on an outer surface of the first substrate; and a second polarizer, disposed on an outer surface of the second substrate, where a polarizing direction of the first polarizer and a polarizing direction of the second polarizer are in parallel to each other.

In this application, the technical problem may be further resolved by using the following technical solutions.

In an embodiment of this application, a fifth switch is further comprised, where a control end of the fifth switch is electrically coupled to a second node, a first end of the fifth switch is electrically coupled to the output pulse signal, and a second end of the fifth switch is electrically coupled to a preset low potential.

In an embodiment of this application, a sixth switch is further comprised, where a control end of the sixth switch is electrically coupled to a second node, a first end of the sixth switch is electrically coupled to the first node, and a second end of the sixth switch is electrically coupled to a preset low potential.

In an embodiment of this application, a pull-down subcircuit is further comprised, and is electrically coupled to the first node, the output pulse signal, and a default low potential of the shift register circuit.

In an embodiment of this application, a pull-down subcircuit controller is further comprised, and is electrically coupled to the default low potential and the pull-down subcircuit of the shift register circuit.

In an embodiment of this application, the first end of the third switch is electrically coupled to the first direct-current signal, to provide a power supply to precharge the shift register circuit.

In an embodiment of this application, the first end of the fourth switch is electrically coupled to the second direct-current signal, to provide a power supply to precharge the shift register circuit.

In an embodiment of this application, the first direct-current signal is used to increase a potential of the control end of the third switch.

In an embodiment of this application, the second direct-current signal is used to increase a potential of the control end of the fourth switch.

In an embodiment of this application, the first direct-current signal and the second direct-current signal take turns to provide a power supply to precharge the shift register circuit.

In this application, in a direct-current precharge mode, an active switch is added and is separately connected to a first direct-current signal and a second direct-current signal, so as to take turns to precharge an increase point, and reduce a pressure time when there is only one switch, thereby extending component service life, and improving product reliability and extending product service life.

### BRIEF DESCRIPTION OF THE DRAWINGS

FIG. 1a is a schematic diagram of an exemplary liquid crystal display;

FIG. 1b is a schematic diagram of a liquid crystal display according to an embodiment of this application;

FIG. 1c is a schematic diagram of an exemplary Thompson circuit;

FIG. 1d is a schematic diagram of a waveform corresponding to an increase point in an exemplary gate drive circuit substrate;

FIG. 2a is a schematic diagram of an exemplary shift register circuit;

FIG. 2b is a schematic diagram of another exemplary shift register circuit;

FIG. 3 is a schematic diagram of a shift register circuit according to an embodiment of this application; and

FIG. 4 is a schematic diagram of a liquid crystal display panel according to another embodiment of this application.

### DETAILED DESCRIPTION

The following embodiments are described with reference to the accompanying drawings, to show examples of particular embodiments implemented by using this application. Direction-related terms provided in this application, for example, “above”, “below”, “front”, “back”, “left”, “right”, “inside”, “outside”, and “lateral face”, merely refer to directions in the accompanying drawings. Therefore, the used direction-related terms are intended for describing and understanding this application, and are not intended for limiting this application.

The accompanying drawings and the descriptions are considered as examples instead of limitation essentially. In the drawings, units having similar structures are represented by a same reference numeral. In addition, for ease of understanding and description, the size and the thickness of each component shown in the accompanying drawings are randomly selected, but this is not limited in this application.

In the accompanying drawings, for clarity, the thickness of a layer, a film, a panel, a region, and the like is greater than that in actual cases. In the accompanying drawings, for ease of understanding and description, the thicknesses of some layers and regions are greater than these in actual cases. It should be understood that, when a component such as a layer, a film, a region, or a base is described as “above” another component, the component may be directly on the another component, or there may be a component disposed therebetween.

In addition, in the specification, unless otherwise described clearly, a word “include” is understood as including the component, but excluding no other component. In addition, in the application, “on” means being located above or below a target component, but does not inevitably mean being located on the top based on a gravity direction.

To further illustrate technical solutions of this application used to achieve a preset invention objective and effects of this application. The following describes in detail specific implementations, structures, features, and effects of the shift register circuit and the display panel using same of this application with reference to the accompanying drawings and preferred embodiments.

A liquid crystal panel in this application may include an active array (TFT) substrate, a color filter (CF) substrate, and a liquid crystal layer formed between the two substrates.

In an embodiment, the liquid crystal panel in this application may be a curved display panel.

In an embodiment of this application, an active array (TFT) and a color filter (CF) may be formed on a same substrate.

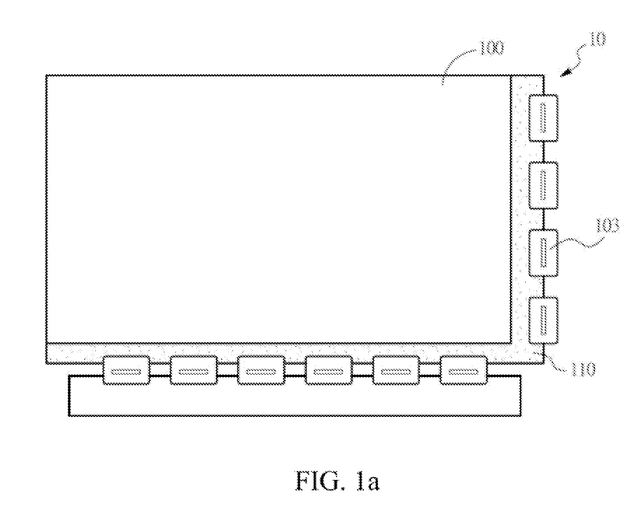

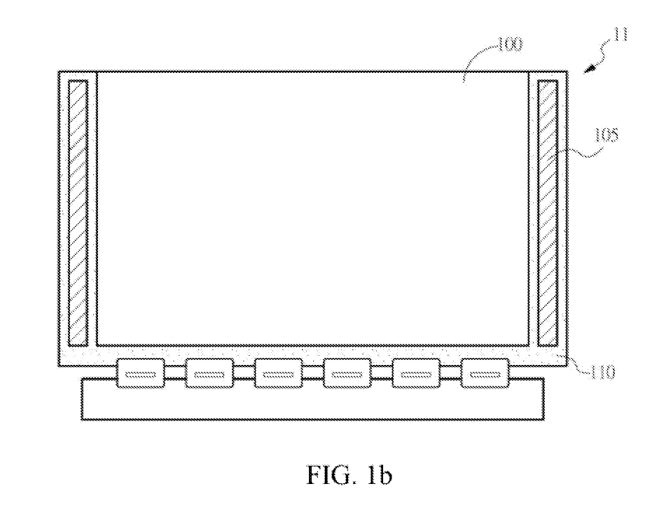

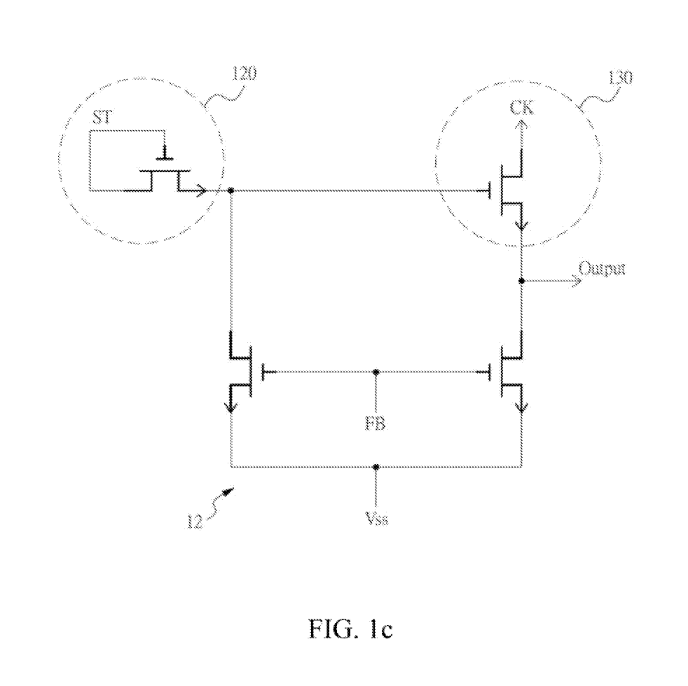

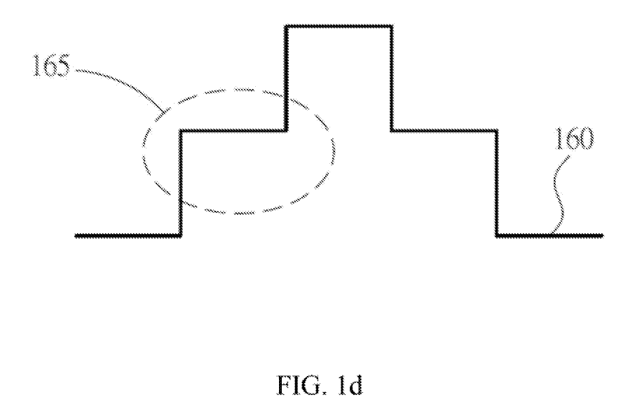

FIG. 1a is a schematic diagram of an exemplary liquid crystal display. Referring to FIG. 1a, the liquid crystal display 10 is provided, including a CF substrate 100, an active array substrate 110, and a drive chip 103 configured to drive a circuit.

FIG. 1b is a schematic diagram of a liquid crystal display according to an embodiment of this application. Referring to FIG. 1b, in this embodiment of this application, the liquid crystal display 11 having a gate driver on array (GOA) is provided, including a color filter substrate 100, an active array substrate 110, and a GOA 105, so as to manufacture a gate drive circuit on the array substrate 110.

FIG. 1c is a schematic diagram of an exemplary Thompson circuit. Referring to FIG. 1c, the Thompson circuit 12 is provided, including an input pulse signal circuit 120 and a frequency signal circuit 130. The input pulse signal circuit 120 is configured to provide a precharge power supply to the Thompson circuit 12. When the frequency signal circuit 130 provides a frequency signal for coupling, a high voltage level is reached at an increase point.

FIG. 1d is a schematic diagram of a waveform corresponding to an increase point in an exemplary gate drive circuit substrate. Referring to FIG. 1d, the waveform 160 of the increase point of the gate drive circuit substrate is provided. The waveform 160 has a high voltage level 165.

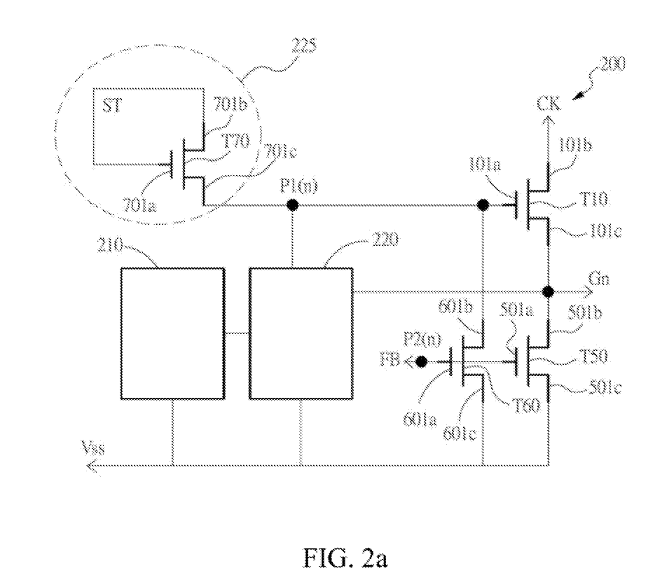

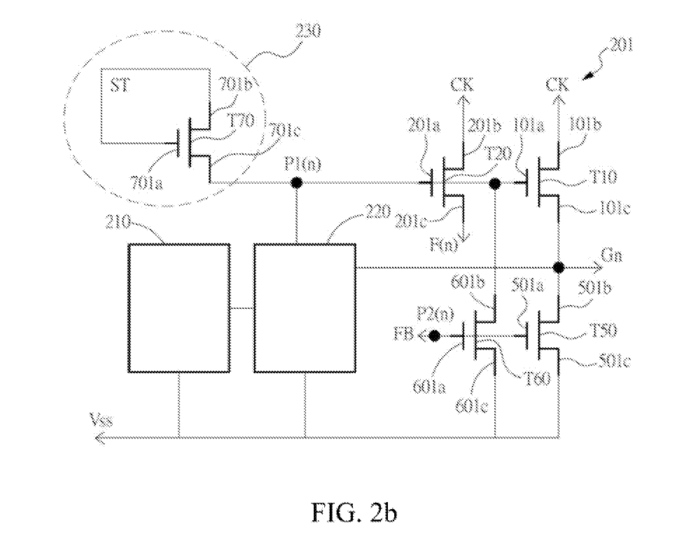

FIG. 2a is a schematic diagram of an exemplary shift register circuit. Referring to FIG. 2a, the shift register circuit 200 is provided, including a plurality of shift registers. Each shift register includes: a first switch T10, where a control end 101a of the first switch T10 is electrically coupled to a first node P1(n), a first end 101b of the first switch T10 is electrically coupled to a frequency signal CK, and a second end 101c of the first switch T10 is electrically coupled to an output pulse signal Gn; a fifth switch T50, where a control end 501a of the fifth switch T50 is electrically coupled to a second node P2(n), a first end 501b of the fifth switch T50 is electrically coupled to the output pulse signal Gn, and a second end 501c of the fifth switch T50 is electrically coupled to a preset low potential Vss; a sixth switch T60, where a control end 601a of the sixth switch T60 is electrically coupled to a second node P2(n), a first end 601b of the sixth switch T60 is electrically coupled to the first node P1(n), and a second end 601c of the sixth switch T60 is electrically coupled to a preset low potential Vss; and an input pulse signal circuit 225 including a seventh switch T70, where a control end 701a of the seventh switch T70 is electrically coupled to an input pulse signal ST, a first end 701b of the seventh switch T70 is electrically coupled to the input pulse signal ST, and a second end 701c of the seventh switch T70 is electrically coupled to the first node P1(1).

In an embodiment, a pull-down subcircuit 220 is further included, and is electrically coupled to the first node P1(n), the output pulse signal Gn, and a default low potential Vss of the shift register circuit 200.

In an embodiment, a pull-down subcircuit controller 210 is further included, and is electrically coupled to the default low potential Vss and the pull-down subcircuit 220 of the shift register circuit 200.

FIG. 2b is a schematic diagram of another exemplary shift register circuit. Referring to FIG. 2b, the shift register circuit 201 is provided, including a plurality of shift registers. Each shift register includes: a first switch T10, where a control end 101a of the first switch T10 is electrically coupled to a first node P1(n), a first end 101b of the first switch T10 is electrically coupled to a frequency signal CK, and a second end 101c of the first switch T10 is electrically coupled to an output pulse signal Gn; a second switch T20, where a control end 201a of the second switch T20 is electrically coupled to the first node P1(n), a first end 201b of the second switch T20 is electrically coupled to the frequency signal CK, and a second end 201c of the second switch T20 is electrically coupled to a control signal F(n); a fifth switch T50, where a control end 501a of the fifth switch T50 is electrically coupled to a second node P2(n), a first end 501b of the fifth switch T50 is electrically coupled to the output pulse signal Gn, and a second end 501c of the fifth switch T50 is electrically coupled to a preset low potential Vss; a sixth switch T60, where a control end 601a of the sixth switch T60 is electrically coupled to a second node P2(n), a first end 601b of the sixth switch T60 is electrically coupled to the first node P1(n), and a second end 601c of the sixth switch T60 is electrically coupled to a preset low potential Vss; and an input pulse signal circuit 230 including a seventh switch T70, where a control end 701a of the seventh switch T70 is electrically coupled to an input pulse signal ST, a first end 701b of the seventh switch T70 is electrically coupled to the input pulse signal ST, and a second end 701c of the seventh switch T70 is electrically coupled to the first node P1(1).

In an embodiment, a pull-down subcircuit 220 is further included, and is electrically coupled to the first node P1(n), the output pulse signal Gn, and a default low potential Vss of the shift register circuit 201.

In an embodiment, a pull-down subcircuit controller 210 is further included, and is electrically coupled to the default low potential Vss and the pull-down subcircuit 220 of the shift register circuit 201.

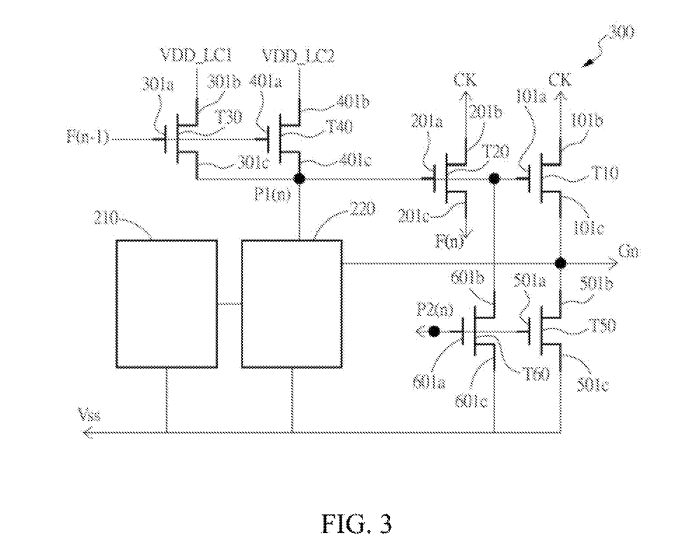

FIG. 3 is a schematic diagram of a shift register circuit according to an embodiment of this application. Referring to FIG. 3, in this embodiment of this application, the shift register circuit 300 is provided, including a plurality of shift registers. Each shift register includes: a first switch T10, where a control end 101a of the first switch T10 is electrically coupled to a first node P1(n), a first end 101b of the first switch T10 is electrically coupled to a frequency signal CK, and a second end 101c of the first switch T10 is electrically coupled to an output pulse signal Gn; a second switch T20, where a control end 201a of the second switch T20 is electrically coupled to the first node P1(n), a first end 201b of the second switch T20 is electrically coupled to the frequency signal CK, and a second end 201c of the second switch T20 is electrically coupled to a control signal F(n); a third switch T30, where a control end 301a of the third switch T30 is electrically coupled to a control signal F(n−1), a first end 301b of the third switch T30 is electrically coupled to a first direct-current signal VDD_LC1, and a second end 301c of the third switch T30 is electrically coupled to the first node P1(n); and a fourth switch T40, where a control end 401a of the fourth switch T40 is electrically coupled to the control signal F(n−1), a first end 401b of the fourth switch T40 is electrically coupled to a second direct-current signal VDD_LC2, and a second end 401c of the fourth switch T40 is electrically coupled to the first node P1(n).

In an embodiment, a fifth switch T50 is further included, a control end 501a of the fifth switch T50 is electrically coupled to a second node P2(n), a first end 501b of the fifth switch T50 is electrically coupled to the output pulse signal Gn, and a second end 501c of the fifth switch T50 is electrically coupled to a preset low potential Vss.

In an embodiment, a sixth switch T60 is further included, a control end 601a of the sixth switch T60 is electrically coupled to a second node P2(n), a first end 601b of the sixth switch T60 is electrically coupled to the first node P1(n), and a second end 601c of the sixth switch T60 is electrically coupled to a preset low potential Vss.

In an embodiment, a pull-down subcircuit 220 is further included, and is electrically coupled to the first node P1(n), the output pulse signal Gn, and the default low potential Vss of the shift register circuit 300.

In an embodiment, a pull-down subcircuit controller 210 is further included, and is electrically coupled to the default low potential Vss and the pull-down subcircuit 220 of the shift register circuit 300.

In an embodiment, the first end 301b of the third switch T30 is electrically coupled to the first direct-current signal VDD_LC1, to provide a power supply to precharge the shift register circuit 300.

In an embodiment, the first end 401b of the fourth switch T40 is electrically coupled to the second direct-current signal VDD_LC2, to provide a power supply to precharge the shift register circuit 300.

In an embodiment, the first direct-current signal VDD_LC1 is used to increase a potential of the control end 301a of the third switch T30.

In an embodiment, the second direct-current signal VDD_LC2 is used to increase a potential of the control end 401a of the fourth switch T40.

In an embodiment, the first direct-current signal VDD_LC1 and the second direct-current signal VDD_LC2 take turns to provide a power supply to precharge the shift register circuit 300.

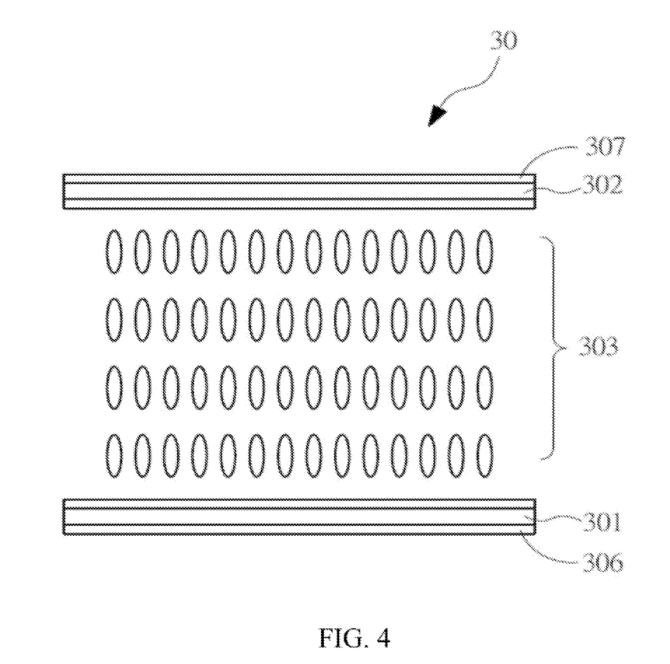

FIG. 4 is a schematic diagram of a liquid crystal display panel according to another embodiment of this application. Referring to FIG. 4 and FIG. 3, in this embodiment of this application, the liquid crystal display panel 30 includes: a first substrate 301 (for example, an active array substrate); a second substrate 302 (for example, a CF substrate), disposed opposite the first substrate 301; a liquid crystal layer 303, disposed between the first substrate 301 and the second substrate 302; the shift register circuit 300, disposed between the first substrate 301 and the second substrate 302 (for example, located on the surface of the first substrate 301); a first polarizer 306, disposed on an outer surface of the first substrate 301; and a second polarizer 307, disposed on an outer surface of the second substrate 302, where a polarizing direction of the first polarizer 306 and a polarizing direction of the second polarizer 307 are in parallel to each other.

In this application, in a direct-current precharge mode, an active switch is added and is separately connected to a first direct-current signal and a second direct-current signal, so as to take turns to precharge an increase point, and reduce a pressure time when there is only one switch, thereby extending component service life, and improving product reliability and extending product service life.

Terms such as “in some embodiments” and “in various embodiments” are used repeatedly. The terms do not represent a same embodiment generally, but may represent a same embodiment. Terms such as “contain”, “have”, and “include” are synonymous unless otherwise described in context.

The foregoing descriptions are merely preferred embodiments of this application, but are not intended to limit this application in any form. This application is disclosed by using the foregoing preferred embodiments, but the embodiments are not intended to limit this application. Without departing from the scope of the technical solutions of this application, a person skilled in the art may make variations by using the foregoing disclosed technical content, or may make modifications equivalent to the variations to obtain equivalent embodiments. Any simple modifications or equivalent variations and modifications made to the foregoing embodiments without departing from the content of the technical solutions of this application and according to technical essence of this application shall still fall within the scope of the technical solutions of this application.

What is claimed is:

1. A shift register circuit, comprising a plurality of shift registers, wherein each shift register comprises:
a first switch, wherein a control end of the first switch is electrically coupled to a first node, a first end of the first switch is electrically coupled to a frequency signal, and a second end of the first switch is electrically coupled to an output pulse signal;
a second switch, wherein a control end of the second switch is electrically coupled to the first node, a first end of the second switch is electrically coupled to the frequency signal, and a second end of the second switch is electrically coupled to a control signal;
a third switch, wherein a control end of the third switch is electrically coupled to a control signal, a first end of the third switch is electrically coupled to a first direct-current signal, and a second end of the third switch is electrically coupled to the first node; and
a fourth switch, wherein a control end of the fourth switch is electrically coupled to the control signal, a first end of the fourth switch is electrically coupled to a second direct-current signal, and a second end of the fourth switch is electrically coupled to the first node.

2. The shift register circuit according to claim 1, further comprising a fifth switch, wherein a control end of the fifth switch is electrically coupled to a second node, a first end of the fifth switch is electrically coupled to the output pulse signal, and a second end of the fifth switch is electrically coupled to a preset low potential.

3. The shift register circuit according to claim 1, further comprising a sixth switch, wherein a control end of the sixth switch is electrically coupled to a second node, a first end of the sixth switch is electrically coupled to the first node, and a second end of the sixth switch is electrically coupled to a preset low potential.

4. The shift register circuit according to claim 1, further comprising a pull-down subcircuit electrically coupled to the first node, the output pulse signal, and a default low potential of the shift register circuit.

5. The shift register circuit according to claim 4, further comprising a pull-down subcircuit controller electrically coupled to the default low potential and the pull-down subcircuit of the shift register circuit.

6. The shift register circuit according to claim 1, wherein the first end of the third switch is electrically coupled to the first direct-current signal, to provide a power supply to precharge the shift register circuit.

7. The shift register circuit according to claim 6, wherein the first direct-current signal is used to increase a potential of the control end of the third switch.

8. The shift register circuit according to claim 1, wherein the first end of the fourth switch is electrically coupled to the second direct-current signal, to provide a power supply to precharge the shift register circuit.

9. The shift register circuit according to claim 8, wherein the second direct-current signal is used to increase a potential of the control end of the fourth switch.

10. The shift register circuit according to claim 1, wherein the first direct-current signal and the second direct-current signal take turns to provide a power supply to precharge the shift register circuit.

11. A liquid crystal display panel, comprising:
a first substrate;
a second substrate, disposed opposite the first substrate;
a liquid crystal layer, disposed between the first substrate and the second substrate;
a first polarizer, disposed on an outer surface of the first substrate; and a second polarizer, disposed on an outer surface of the second substrate, wherein a polarizing direction of the first polarizer and a polarizing direction of the second polarizer are in parallel to each other; and
a shift register circuit, disposed on the first substrate or the second substrate.

12. The liquid crystal display panel according to claim 11, wherein the shift register circuit comprises a plurality of shift registers, and each shift register comprises:
a first switch, wherein a control end of the first switch is electrically coupled to a first node, a first end of the first switch is electrically coupled to a frequency signal, and a second end of the first switch is electrically coupled to an output pulse signal;
a second switch, wherein a control end of the second switch is electrically coupled to the first node, a first end of the second switch is electrically coupled to the frequency signal, and a second end of the second switch is electrically coupled to a control signal;
a third switch, wherein a control end of the third switch is electrically coupled to a control signal, a first end of the third switch is electrically coupled to a first direct-current signal, and a second end of the third switch is electrically coupled to the first node; and
a fourth switch, wherein a control end of the fourth switch is electrically coupled to the control signal, a first end of the fourth switch is electrically coupled to a second direct-current signal, and a second end of the fourth switch is electrically coupled to the first node.

13. The liquid crystal display panel according to claim 12, further comprising a fifth switch, wherein a control end of the fifth switch is electrically coupled to a second node, a first end of the fifth switch is electrically coupled to the output pulse signal, and a second end of the fifth switch is electrically coupled to a preset low potential.

14. The liquid crystal display panel according to claim 12, further comprising a sixth switch, wherein a control end of the sixth switch is electrically coupled to a second node, a first end of the sixth switch is electrically coupled to the first node, and a second end of the sixth switch is electrically coupled to a preset low potential.

15. The liquid crystal display panel according to claim 12, further comprising a pull-down subcircuit electrically coupled to the first node, the output pulse signal, and a default low potential of the shift register circuit.

16. The liquid crystal display panel according to claim 15, further comprising a pull-down subcircuit controller electrically coupled to the default low potential and the pull-down subcircuit of the shift register circuit.
